(19) United States
(12) Patent Application Publication
(10) Pub. No.: US 2016/0035539 A1
(43) Pub. Date: Feb. 4, 2016

(54) Microfabrication

(71) Applicants: Lauri Sainiemi, Espoo (FI); Tapani Levola, Espoo (FI); Pasi Saarikko, Espoo (FI)

(72) Inventors: Lauri Sainiemi, Espoo (FI); Tapani Levola, Espoo (FI); Pasi Saarikko, Espoo (FI)

(21) Appl. No.: 14/447,446

(22) Filed: Jul. 30, 2014

(51) Int. Cl. H01J 37/305

(52) U.S. Cl. CPC H01J 37/3053

(57) ABSTRACT

A microfabrication apparatus for fabricating a microstructure on a substrate is disclosed and comprises a partitioning system arranged to provide an aperture, a particle source that can generate a beam of particles for patterning the substrate and a substrate holder which supports the substrate. Relative motion is effected between the aperture and the substrate over a portion of the substrate's surface so that different points on the surface portion are exposed at different times. Whilst that motion is ongoing, one or more exposure conditions are varied so that the different points are subject to different exposure conditions. Corresponding microfabrication processes and products obtained thereby are also disclosed.

### BACKGROUND

Microfabrication refers to the fabrication of desired structures of micrometre scales and smaller. Microfabrication may involve etching of and/or deposition on a substrate (and possibly etching of and/or deposition on a film deposited on the substrate) to create the desired microstructure on the substrate (or film on the substrate). As used herein, the term “patterning a substrate” or similar encompasses all such etching of/deposition on a substrate or substrate film.

Wet etching involves using a liquid etchant to selectively dislodge parts of a film deposited on a surface of a substrate and/or parts of the surface of substrate itself. The etchant reacts chemically with the substrate/film to remove parts of the substrate/film that are exposed to the etchant. The selective etching may be achieved by depositing a suitable protective layer on the substrate/film that exposes only parts of the substrate/film to the chemical effects of etchant and protects the remaining parts from the chemical effects of the etchant. The protective layer may be formed of a photoresist or other protective mask layer. The photoresist or other mask may be deposited over the whole of an etching surface area then exposed and developed to create a desired “image”, which is then engraved in the substrate/film by the etchant to form a three dimensional structure.

Dry etching involves selectively exposing a substrate/film (e.g. using a similar photoresist mask) to a bombardment of energetic particles to dislodge parts of the substrate/film that are exposed to the particles (sometimes referred to as “sputtering”). An example is ion beam etching in which parts are exposed to a beam of ions. Those exposed parts may be dislodged as a result of the ions chemically reacting with those parts to dislodge them (sometimes referred to as “chemical sputtering”) and/or physically dislodging those parts due to their kinetic energy (sometimes referred to as “physical sputtering”).

In contrast to etching, deposition—such as ion-beam deposition or immersion-based deposition—involves applying material to rather than removing material from a substrate/film.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Nor is the claimed subject matter limited to implementations that solve any or all of the disadvantages noted in the Background section.

According to a first aspect, a microfabrication apparatus for fabricating a microstructure on a substrate is provided. The microfabrication apparatus comprises a partitioning system, a particle source, a substrate holder, a drive mechanism and a controller. The partitioning system is arranged to provide an aperture. The particle source is forward of the aperture and is configured when active to generate a beam of particles for patterning a substrate. The beam is directed towards and encompasses the aperture, and the partitioning system inhibits the passage of the beam other than through the aperture. The substrate holder is configured to support the substrate behind the aperture, thereby exposing the substrate to only those parts of the beam which pass through the aperture. The drive mechanism is coupled to the substrate holder and/or the partitioning system. The controller is configured when the particle source is active to control the drive mechanism to effect relative motion between the aperture and the substrate over a portion of the substrate's surface so that different points on the surface portion are exposed at different times. Whilst that motion is ongoing, the controller is configured to vary one or more exposure conditions so that the different points are subject to different exposure conditions, those conditions determining the manner in which the substrate is patterned by the beam at those points, thereby fabricating a microstructure on the surface portion having one or more spatially varying characteristics.

According to a second aspect, a microfabrication process for fabricating a microstructure on a substrate is provided, in which the substrate is supported behind an aperture provided by a partitioning system with a particle source forward of the aperture. The particle source is configured when active to generate a beam of particles for patterning the substrate, which is directed towards and encompasses the aperture. The partitioning system inhibits the passage of the beam other than through the aperture so that the substrate is exposed to only those parts of the beam which pass through the aperture. In a first process step, when the particle source is active, relative motion between the aperture and the substrate is effected over a portion of the substrate's surface so that different points on the surface portion are exposed at different times. In a second process step, whilst that motion is ongoing, one or more exposure conditions are varied so that the different points are subject to different exposure conditions, those conditions determining the manner in which the substrate is patterned by the beam at those points, thereby fabricating a pattern on the surface portion having one or more spatially varying characteristics.

According to a third aspect, products obtained by any of the manufacturing processes and/or using any of the manufacturing apparatuses disclosed herein are provided.

### BRIEF DESCRIPTION OF FIGURES

To aid understanding of the subject matter, reference will now be made by way of example only to the following drawings in which:

FIG. 1A is a schematic plan view of an optical component;

FIG. 1B is a schematic illustration of an optical component, shown interacting with incident light and viewed from the side;

FIG. 2A is a schematic illustration of a straight binary grating, shown interacting with incident light and viewed from the side;

FIG. 2B is a schematic illustration of a slanted binary grating, shown interacting with incident light and viewed from the side;

FIG. 2C is a schematic illustration of an overhanging triangular grating, shown interacting with incident light and viewed from the side;

FIG. 3A is a schematic view of a microfabrication system from the side;

FIG. 3B is a schematic plan view of part of a microfabrication system;

FIG. 4 is a schematic illustration showing exemplary operation of a microfabrication system;

FIG. 5 is a schematic block diagram of a microfabrication apparatus.

It should be noted that the drawings are not necessarily to scale unless otherwise indicated. Emphasis is instead placed on explaining the principles of particular embodiments.

### DETAILED DESCRIPTION

Microfabrication processes may be used in the manufacturing of optical components. One example is the fabrication of optically diffractive structures (transmissive and/or reflective) that cause diffraction of visible light. Diffraction occurs when a propagating wave interacts with a structure, such as an obstacle or slit. Diffraction can be described as the interference of waves and is most pronounced when that structure is comparable in size to the wavelength of the wave. Optical diffraction of visible light is due to the wave nature of light and can be described as the interference of light waves. Visible light has wavelengths between approximately 390 and 700 nanometres (nm) and diffraction of visible light is most pronounced when propagating light encounters structures similar scale e.g. of order 100 or 1000 nm in scale.

One example of a diffractive structure is a periodic structure. Periodic structures can cause diffraction of light which is typically most pronounced when the periodic structure has a spatial period of similar size to the wavelength of the light. Types of periodic structures include, for instance, surface modulations on a surface of an optical component, refractive index modulations, holograms etc. When propagating light encounters the periodic structure, diffraction causes the light to be split into multiple beams in different directions. These directions depend on the wavelength of the light thus diffractions gratings cause dispersion of polychromatic (e.g. white) light, whereby the polychromatic light is split into different coloured beams travelling in different directions.

When the period structure is on a surface of an optical component, it is referred to a surface grating. When the periodic structure is due to modulation of the surface itself, it is referred to as a surface relief grating (SRG). An example of a SRG is uniform straight grooves in a surface of an optical component that are separated by uniform straight groove spacing regions. Groove spacing regions are referred to herein as “lines”, “grating lines” and “filling regions”. The nature of the diffraction by a SRG depends both on the wavelength of light incident on the grating and various optical characteristics of the SRG, such as line spacing, groove depth and groove slant angle. An SRG can be fabricated by way of a suitable microfabrication process, which may involve etching of and/or deposition on a substrate to fabricate a desired periodic microstructure on the substrate. The substrate may be the optical component itself or a production master such as a mould for manufacturing optical components.

SRGs have many useful applications. One example is an SRG light guide application. A light guide is an optical component used to transport light by way of internal reflection (e.g. total internal reflection) within the light guide. A light guide may be used, for instance, in a light guide-based display system for transporting light of a desired image from a light engine to a human eye to make the image visible to the eye. Incoupling and outcoupling SRGs on surface(s) of the light guide can be used for inputting light to and outputting light from the waveguide respectively.

Embodiments will now be described in the context of the manufacturing of SRGs.

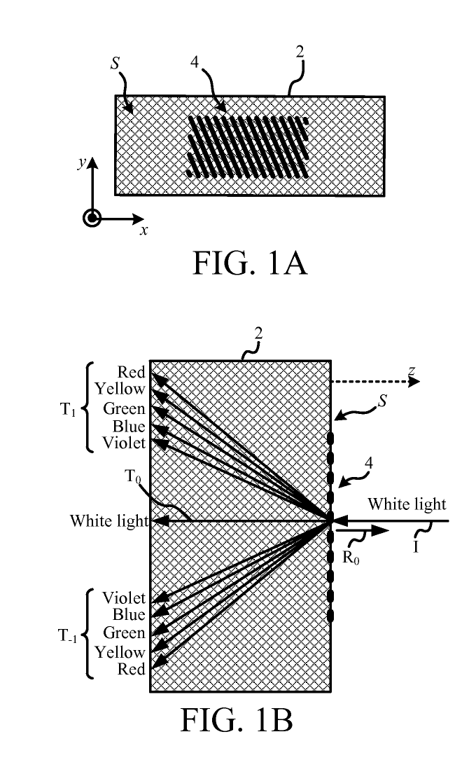

FIGS. 1A and 1B show from the top and the side respectively a substantially transparent optical component 2, such as a wave guide, having an outer surface S. At least a portion of the surface S exhibits surface modulations that constitute a SRG pattern 4, which is one example of a microstructure. Such a portion is referred to as a “grating area”. The surface S lies substantially in a plane defined by x and y axes as shown in FIG. 1A. The z-axis represents a direction perpendicular to that plane and thus a direction substantially perpendicular to the surface S (referred to as the “the normal” to the surface S).

FIG. 1B shows the optical component 2, and in particular the grating 4, interacting with an incoming illuminating light beam I that is inwardly incident on the SRG 4. The light I is white light in this example, and thus has multiple colour components. The light I interacts with the grating 4 which splits the light into several beams directed inwardly into the optical component 2. Some of the light I may also be reflected back from the surface S as a reflected beam R0. A zero-order mode inward beam T0 and any reflection R0 are created in accordance with the normal principles of refraction and reflection (not diffraction per se). In contrast, inward non-zero-order (±n-order) mode beams arise as a result of diffraction (which can be explained as wave interference). FIG. 1B shows first-order inward beams T1, T-1; it will be appreciated that higher-order beams may or may not also be created depending on the configuration of the optical component 2. Because the nature of the diffraction is dependent on wavelength, for higher-order modes, different colour components (i.e. wavelength components) of the incident light I are, when present, split into beams of different colours at different angles of propagation relative to one another as illustrated in FIG. 1B.

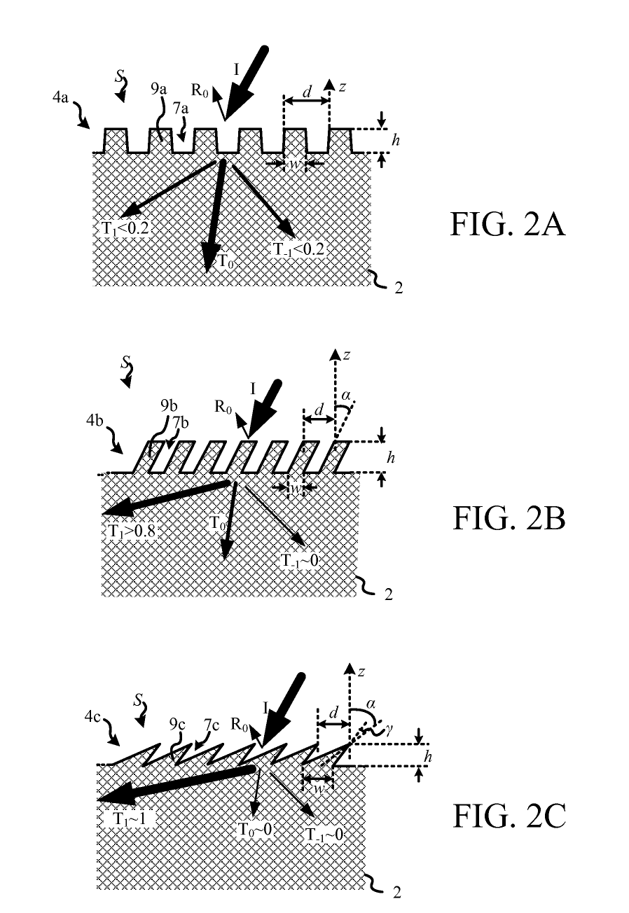

FIGS. 2A-2C are close-up schematic cross sectional views of different exemplary SRG patterns 4a-4c (collectively referenced as 4 herein) that may formed by modulation of the surface S of the optical component 2 (which is viewed from the side in these figures). Light beams are denoted as arrows whose thicknesses denote approximate relative intensity (with higher intensity beams shown as thicker arrows).

FIG. 2A shows an example of a “straight binary grating” pattern 4a. The straight binary grating 4a is formed of a series of grooves 7a in the surface S separated by protruding groove spacing regions 9a which are also referred to herein as “filling regions”, “grating lines” or simply “lines”. The pattern 4a has a spatial period of d (referred to as the “grating period”), which is the distance over which the modulations' shape repeats. The grooves 7a have a depth h and have substantially straight walls and substantially flat bases. As such, the filling regions have a height h and a width that is substantially uniform over the height h of the filling regions, labelled “w” in FIG. 2A (with w being some fraction f of the period: w=f*d).

For a straight binary grating, the walls are substantially perpendicular to the surface S. For this reason, the grating 4a causes symmetric diffraction of incident light I that is entering perpendicularly to the surface, in that each +n-order mode beam (e.g. T1) created by the pattern 4a has substantially the same intensity as the corresponding -n-order mode beam (e.g. T-1), typically less than about one fifth (0.2) of the intensity of the incident beam I.

FIG. 2B shows an example of a “slanted binary grating” pattern 4b. The slanted pattern 4b is also formed of grooves, labelled 7b, in the surface S having substantially straight walls and substantially flat bases separated by lines 9b of width w. However, in contrast to the straight pattern 4a, the walls are slanted by an amount relative to the normal, denoted by the angle a in FIG. 2B. The grooves 7b have a depth h as measured along the normal. Due to the asymmetry introduced by the non-zero slant, ±n-order mode inward beams travelling away from the slant direction have greater intensity that their ∓n-order mode counterparts (e.g. in the example of FIG. 2B, the T1 beam is directed away from the direction of slant and has usually greater intensity than the T-1 beam, though this depends on e.g. the grating period d); by increasing the slant by a sufficient amount, those ∓n counterparts can be substantially eliminated (i.e. to have substantially zero intensity). The intensity of the T0 beam is typically also reduced very much by a slanted binary grating such that, in the example of FIG. 2B, the first-order beam T1 typically has an intensity of at most about four fifths (0.8) the intensity of the incident beam I.

The binary patterns 4a and 4b can be viewed as spatial waveforms embedded in the surface S that have a substantially square wave shape (with period d). In the case of the pattern 4b, the shape is a skewed square wave shape skewed by α.

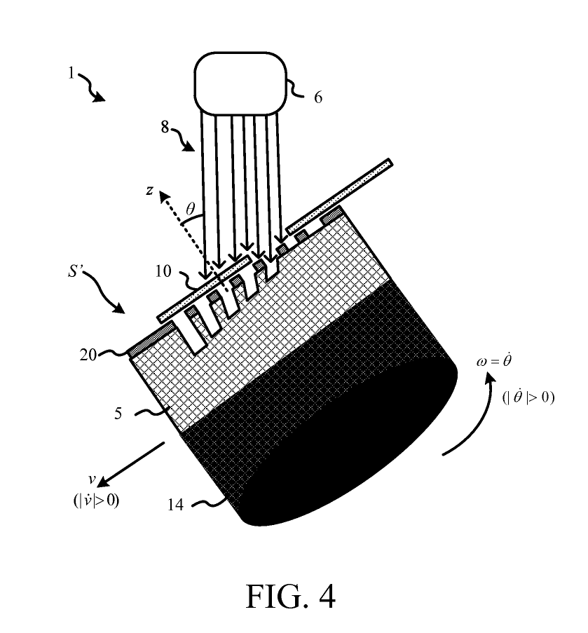

FIG. 2C shows an example of an “overhanging triangular grating” pattern 4c which is a special case of an overhanging “trapezoidal grating” pattern. The triangular pattern 4c is formed of grooves 7c in the surface S that are triangular in shape (and which thus have discernible tips) and which have a depth h as measured along the normal. Filling regions 9c take the form of triangular, tooth-like protrusions (teeth), having medians that make an angle α with the normal (α being the slant angle of the pattern 4c). The teeth have tips that are separated by d (which is the grating period of the pattern 4c), a width that is w at the base of the teeth and which narrows to substantially zero at the tips of the teeth. For the pattern of FIG. 4c, w≈d, but generally can be w<d. The pattern is overhanging in that the tips of the teeth extend over the tips of the grooves. It is possible to construct overhanging triangular grating patterns that substantially eliminate both the transmission-mode T0 beam and the ∓n-mode beams, leaving only ±n-order mode beams (e.g. only T1). The grooves have walls which are at an angle γ to the median (wall angle).

The pattern 4c can be viewed as a spatial waveform embedded in S that has a substantially triangular wave shape, which is skewed by α.

Other gratings are also possible, for example other types of trapezoidal grating patterns (which may not narrow in width all the way to zero), sinusoidal grating patterns etc. Such other patterns also exhibit depth h, linewidth w, slant angle α and wall angles γ which can be defined in a similar manner to FIG. 2A-C

The techniques described below enable gratings (including, for example, binary trapezoidal (e.g. triangular) and sinusoidal gratings) to be manufactured with variable h and/or α. That is, with depths and/or slants which vary as respective functions h(x,y) and α(x,y) of position on the surface S. In light guide-based display applications (e.g. where SRGs are used for coupling of light into and out of a light guide of the display system), d is typically between about 250 and 500 nm, and h between about 30 and 400 nm. The slant angle α is typically between about 0 and 45 degrees (such that slant direction is typically elevated above the surface S by an amount between about 45 and 90 degrees).

An SRG has a diffraction efficiency defined in terms of the intensity of desired diffracted beam(s) (e.g. T1) relative to the intensity of the illuminating beam I, and can be expressed as a ratio η of those intensities. As will be apparent from the above, slanted binary gratings (e.g. 4b—up to η≈0.8 if T1 is the desired beam) can achieve higher efficiency than non-slanted grating (e.g. 4a—only up to about η≈0.2 if T1 is the desired beam). With overhanging triangular gratings, it is possible to achieve near-optimal efficiencies of η≈1.

The performance of a SRG light guide-based display is strongly dependent on the efficiency of the gratings and their dependence on the incidence angle of the incoming light. To achieve high diffraction efficiency, slanted gratings may be used. Suitable patterns can be fabricated on quartz and silicon masters (for transferring to optical components) with aid of ion beam etching (IBE). However, the technology is not limited to these materials.

Using a standard commercial IBE system, it is impossible to create grating areas with variable depth h and/or variable slanting angle α. However, both types of variation may be desirable to optimize the performance of SRG light guides. More generally, micro-and nanofabrication rarely provide the possibility to realize structures that have continuously changing depth or thickness profiles (if ever). The changes are always stepwise, which can ruin the performance of the application. This is true e.g. in the case of SRG light guide based displays.

In contrast, in the following, a customized shutter mechanism is considered which can achieve constantly varying etching profiles, i.e. positionally changing depth h and/or slant angle α. The shutter mechanism is disposed between an ion source (e.g. ion gun) of the IBE tool and a substrate holder configured to hold a substrate to be patterned. The substrate may, for instance, be a quartz substrate to be patterned with an SRG to create a desired optical component, or a silicone master for moulding optical components (e.g. from a polymer).

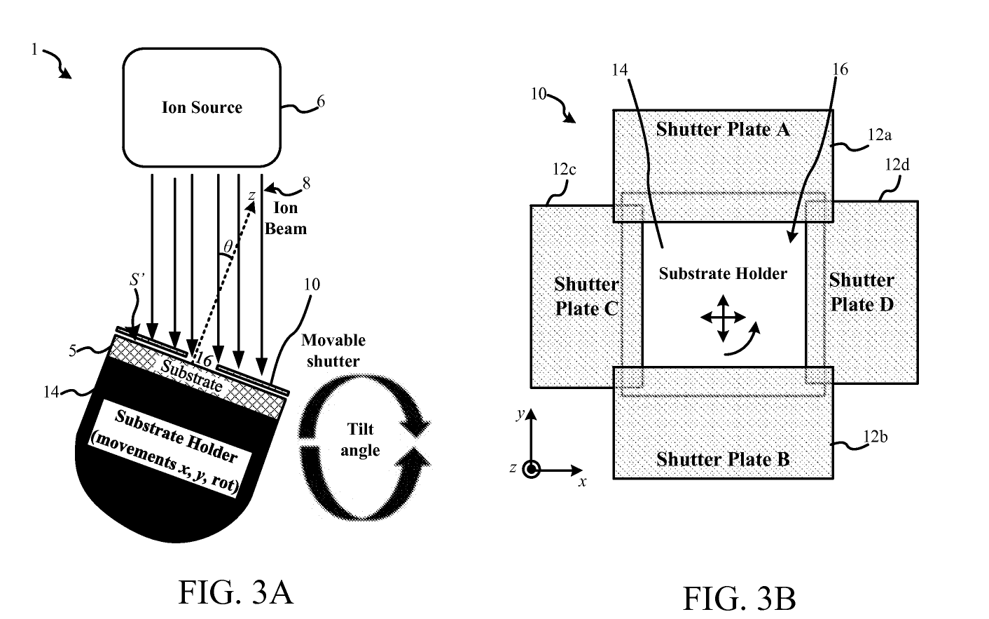

In the following examples, a substrate (5—FIG. 3A) has an outer surface S′ that patterned on by way of microfabrication. The final patterned substrate may itself be for use as optical components (e.g. wave guides) in an optical system (e.g. display system) or it may for use as a production master for manufacturing such components e.g. moulds for moulding such components from polymer. Where the substrate 5 is an optical component, the substrate's surface S′ is the same as the surface S shown FIGS. 2A-2C. When the substrate 5 is a master (e.g. a mould) S′ still corresponds to S in that the structure of S′ is transferred (that is, copied) to S as part the manufacturing (e.g. moulding) process. The surface S′ lies substantially in a plane referred to herein as the xy-plane having x and y coordinates equivalent to those shown in FIG. 1A in relation to the surface S, with points in the xy-plane (and thus on the surface S′) being denoted (x,y).

The substrate is patterned over at least a portion of its surface (grating area) to form a grating, which may then be transferred to other components where applicable. The dimensional size of the grating area (e.g. being of order mm, cm or higher) is significantly larger than the grating period—there typical being e.g. thousands of lines/grooves per mm of grating. As such, even though there are a discrete number of lines/grooves in the grating area, this number is sufficiently large that grating characteristics can be viewed as mathematical functions over a substantially continuous domain of geometric points r=(x, y) (bold typeface denoting xy-vectors). For this reason, the general notation c(x,y) (or similar) is adopted for grating characteristics hereinbelow. Where applicable, references to “points” on surface portion (or similar) are to be construed accordingly, including in the claims below.

The linewitdh w(x,y), grating depth h(x,y) and slant α(x,y) are examples of such grating characteristics. The techniques below enable grating patterns to be manufactured on a surface portion with linewidth w(x,y) that varies over that surface portion and, moreover, which does so gradually i.e. as a substantially continuous mathematical function over said substantially continuous domain of points.

A grating characteristic c(r)=c(x, y) is considered to spatially vary over a surface portion in the present context provided that grating characteristic c(r) changes by an overall amount ΔC=max c(r)−min c(r) that is significant as compared with a characteristic scale C of the grating characteristic c(r) itself, such as C=max |c(r)|. Examples of significant changes include when ΔC is the same order of magnitude, or one order of magnitude lower than, C. For example, for the grating patterns mentioned above with reference to FIGS. 2A-2C; the depth would be considered to be spatially varying in the present context at least when the depth changes by an overall amount ΔH of order of 10 nm or more; the slant would be considered to be spatially varying in the present context at least when the slant changes by an overall amount ΔA of order of 5 degrees or more. Where a grating characteristic exhibits only small, unintended variations, such as small, unintended variations arising from undesired manufacturing inaccuracies or imprecisions and/or other variations restricted to a similar scale, that characteristic is not considered to be spatially varying in the context of the present disclosure.

Spatial variations are considered gradual (substantially continuous) providing that grating characteristic's spatial gradient ∇c(x, y)−where ∇=(∂ₓ, ∂_{y}) is the gradient function for the xy-plane, is sufficiently small at all points r=(x, y) on the surface portion so that changes in the grating characteristic c(r) over small distances of order d are always at least 3 orders of magnitude smaller than ΔC at all points r i.e. so that |∇c(r)|*d˜10⁻³*ΔC or less for all r on the surface portion.

For instance, the disclosed techniques enable gratings to be manufactured with a gradually varying depth h(x,y) which does not change by more than of the order of 10⁻² nm over a single grating period so that the depth gradient ∇h(x, y) does not exceed an amount of the order of 10⁻⁴ or 10⁻⁵—at any point on the surface portion. Gratings can also be manufactured with gradually varying slant a(x,y) which does not change by more than about 10⁻³ degrees over a single grating period so that the slant gradient ∇α(x, y) does not exceed an amount of the order of 10⁻⁵ or 10⁻⁶ degrees/nm—at any point on the surface portion.

FIG. 3A is a schematic illustration showing, from the side, components of a microfabrication system which forms part of a microfabrication tool for fabricating a microstructure on a substrate (sample) 5 in a microfabrication process. The system 1 comprises an ion source in the form of an ion gun 6, a substrate holder (sample holder) 14, which supports the substrate 5, and a partitioning system in the form of a shutter mechanism 10.

The ion gun 6 can be activated to generate a beam of ions 8 for etching a substrate, either by chemically reacting with parts of the substrate that it encounters, physically dislodging those parts, or a combination of both. The ions may for instance be of a type that react with quartz or silicone (or other suitable material) as desired, and suitable beam compositions will be apparent to the skilled person.

The shutter mechanism is disposed between the substrate holder 14 and the ion source 6 and is arranged to provide an aperture 16. The ion gun 6 is forward of the aperture 16 and is arranged such that the beam 8 is directed towards and encompasses the aperture 16. The substrate 5 is supported behind the aperture so that a region of the outer surface S′ of the substrate 5 is visible through the aperture, the visible region having substantially the same size (i.e. area) as the aperture. The shutter mechanism 10 is composed of a material that does not or only minimally reacts with the ions. The shutter mechanism 10 thus inhibits the passage of the beam 8 other than through the aperture, such that the substrate is exposed to only those parts of the beam (i.e. to those beam particles) which pass through the aperture. In this way, the ions of the beam 8 only interact with the region of the surface S′ that is visible through the aperture 16, with the remaining parts of the surface S′ being shielded from the beam 8. The tool may be contained a process chamber (not shown) to substantially isolate it from the surrounding environment.

The beam 8 is substantially collimated to effect anisotropic (i.e. directional) etching, as discussed in more detail below. The collimation can be achieved, for instance, by inducing suitable electric potentials in the grids inside the ion source 6.

A tilting angle θ between the ion source 6 and the substrate holder 14 (referred to as the “angle of beam incidence”) can also be varied to create changing slanting angles. The substrate holder 14 and shutter mechanism 10 can both be tilted relative to the ion gun 6 to vary the tilt angle θ between the normal to the surface S′ (labelled as direction z) and the direction of the ion beam 8, such that the shutter tilts with the substrate holder relative to the beam 8. As mentioned, the surface S′ lies substantially in a plane referred to herein as the xy-plane; that is, the xy-plane is defined relative to the surface S′ of the substrate 5 and can be considered to tilt with the surface S′ as θ is varied. Although only a single tilting angle θ is shown in FIG. 3A (representing angular variation in the plane of the page), the apparatus can also be tilted perpendicular to this (that is, into/out of the page as the figure is viewed) to provide any desired orientation of the surface S′ relative to the beam 8. The tilting angle θ is also the angle of incidence of the beam 8 relative to the surface S′ i.e. θ is the amount by with the direction of the beam 8 deviated from the normal to the surface S′ (referred to herein as the “angle of beam incidence”).

The aperture 16 provided by the shutter mechanism 10 has a programmable aperture size. The shutter mechanism 10 may also provide programmable control over the position of the etching aperture 16, with the shutter mechanism 10 being controllable to move the aperture relative to the holder 14 in the xy-plane in some or all directions in the xy-plane. The movements of the aperture 16 (x, y) can be synchronized with the movements (x, y and rotation) of the substrate holder 14 in order to achieve variable and continuously changing etching depths at any point on the substrate. The beam 8 is wide enough to (that is has a beam diameter/area sufficient to) keep the aperture 16 encompassed as it moves relative to the ion gun 6 and/or changes size.

The substrate holder 14 is moveable in the xy-plane in some or all directions underneath the shutter without moving the shutter, which makes it possible to considerably reduce the sizes of the ion gun 6 and the whole tool (as the beam 8 need only encompasses a fixed or maximum aperture size at a fixed aperture location relative to the gun 6). This can reduce the overall cost of the tool considerably.

The shutter mechanism 10 can be constructed e.g. from two separate shutter plate pairs i.e. from four shutter plates in total. An exemplary shutter mechanism 10 is depicted in FIG. 3B, which is a plan view of part of the tool providing a cross sectional view of the tool in the xy-plane. Four controllable shutter plates 12a-12d are shown which constitute the shutter mechanism 10. The aperture 16 is an open region defined by the intersection of the plates' inner edges. The substrate holder 14 can be seen underneath the shutter 10 (that is underneath the pates 12). A pair of plates 12a, 12b can be moved in a first direction in the xy-plane—labelled as the y direction—and a second pair of plates 12c, 12d can be moved in a second direction in the xy-plane—labelled as the x direction—substantially perpendicular to the first direction. Each of the plates 12 can be moved individually e.g. using in-vacuum stepper motors (e.g. commercially available in-vacuum stepper motors) coupled to the plates 12 to form different aperture configurations of different sizes and shapes. The substrate holder 15 can be separately moved and rotated in the xy-plane. Using this construction, the shape of the etching aperture is always rectangular, but otherwise its size can be changed freely—including during the ion beam etching process.

The plates 12 are made of molybdenum or other low sputter yield material; there are many such suitable materials, for example some ceramics. Molybdenum is suitable because of its easy manufacturability. The low sputter yield composition of the plates 12 enables them to effectively inhibit the passage of the beam 8 other than through the aperture 16. Each plate 12 can be moved separately using in-vacuum stepper motors.

As indicated, the shutter mechanism 10 is placed into the process chamber so that the plates 12 are between the ion source 6 and the substrate holder 14. The shutter plates 12 are positioned as close to the surface S′ of the substrate 5 as possible to improve the etching accuracy e.g. with a separation of about 1 mm (or less, depending on e.g. the loading mechanism of the substrates). At the upper limit, a maximum separation of about 5 mm may be imposed. The mounting of the shutter mechanism 10 into the process chamber is done in a manner which allows independent movement (xy-planar motion and rotation) of the substrate holder 14 without moving the shutter 10. However, when the substrate holder 14 is tilted relative to ion source 6, the shutter follows the tilting as shown in FIG. 3A (the substrate holder and the partitioning system thereby remaining aligned with one another). If the etching aperture 16 is approximately in the middle of the chamber while the substrate is moving, the diameter of the ion source is defined by the largest portion of the surface S′ that is to be exposed at any given time during the microfabrication process taking in to account the beam homogeneity (as this sets the maximum required aperture size, and the beam need only encompasses the aperture). This is in contrast to existing ion-beam etching techniques where the size of the substrate (that is the size of the surface S′, or at least the portion of S′ to be etched) dictates the ion source diameter. Therefore the size and the cost of the IBE tool can be reduced considerably in accordance with the present teachings.

Alternatively, the shutter mechanism can be mounted on a sample holder which can only be rotated relative to shutter (no movement in the xy-plane). This allows the shutter mechanism to be fitted inside a standard, commercially available IBE tool. This may require a larger ion source, because the ion beam must cover the whole substrate area. In this scenario, relative xy-planar motion between the aperture and holder is effected by driving the shutter (and not the holder).

As indicated, the apparatus 1 can be used in the fabrication of grating areas with continuously changing depth and/or slanting angle. Slanted gratings with continuously changing depth and/or slanting angle can be realized with both of the aforementioned shutter configurations.

A grating pattern can be manufactured on the substrate by first coating the whole (or most) of the surface S′ in a chromium layer or other protective mark layer (e.g. another metallic layer). The mask layer can then be covered in a photoresist. A two-dimensional image of a desired grating pattern can then be projected onto photoresist using conventional techniques. The photoresist is then developed to remove either the exposed parts or the non-exposed parts (depending on the composition of the photoresist), leaving selective parts of the mask layer visible (i.e. revealing only selective parts) and the remaining parts covered by the remaining photoresist. The uncovered parts of the mask layer can then be removed using conventional etching techniques e.g. an initial ion beam etching process which removes the uncovered parts of the mask but not the parts covered by the photoresist, and which does not substantially affect the substrate itself.

The mask layer material is chosen so that it inhibits the passage of ion of the ion beam 8 i.e. a mask material is chosen that is resistant to the effects of the beam 8, and which thus protects any regions of the surface S′ from the effects of the beam 8 that are covered by the mask during the ion beam etching of the substrate. In this manner, when the ion beam 8 is directed towards the substrate, only those parts of surface S′ not covered by the mask layer react with the ion beam 8, with the ion beam creating protrusions in the surface S′ in those parts (by chemically and/physically dislodging substrate material from only the revealed parts). Thus, the two-dimensional grating image is etched into the substrate 5 by the ion beam to create a three-dimensional grating structure. Because the ion beam 8 is substantially collimated, the etching is anisotropic, resulting in protrusions having substantially straight sides.

To fabricate a diffraction pattern of the type shown in FIGS. 2A and 2B, substantially uniform rectangles of the mask (having a period d and width w and a length that spans the portion of the surface S′ on which the pattern is to be fabricated, which may be the entirety of the surface S′) may be retained on the surface S′, leaving substantially uniform rectangles of the mask which have the same length and a width d*(1−f) (which may the same or similar to the line width w) on the surface S′.

Alternatively a photoresist layer may be applied to the substrate directly and selective regions of the photoresist so that the photo resist functions in a similar manner to the aforementioned mask. However, using a separate metallic mask layer can facilitate better selectivity of etching.

A grating exhibiting a continuous depth gradient can be fabricated e.g. by moving a constant sized etching aperture or by moving the substrate holder underneath a constant sized etching aperture (or both) during the ion beam etching process with variable speed, or more precisely (vector) velocity in the xy-plane. Alternatively, the aperture size may also be varied at the same time.

In more general terms, relative xy-motion between a (constant or variable sized) aperture and a substrate can be effected to create a pattern of changing depth. Varying the speed of the relative motion causes varying exposure time τ (one example of an exposure condition) i.e. with different points (x,y) on at least a portion of the surface S′ being subject to different “localized” exposure times τ(x,y). When the relative aperture-substrate motion is faster (resp. slower), points (x,y) remain exposed for less (resp. more) time—thus the exposure time can be increased (resp. decreased) by slowing down (resp. speeding up) the relative motion. Whilst the relative motion is ongoing, the aperture can be considered as moving in the xy-plane relative to the surface S′ (regardless of which components are actually being driven).

The speed is varied continuously (i.e. smoothly) as a function of time which causes the localized exposure time τ(x,y) to which each point (x,y) is subject to vary correspondingly smoothly as a function of position in the xy-plane (xy-position). This causes a structure with depth to be created with spatially varying depth h(x,y) (which corresponds to “h” as shown in FIGS. 2A-2C) that varies as a function of xy-position in a correspondingly smooth manner as the depth h(x,y) of the structure at a point (x,y) is determined by the localized exposure time τ(x,y) e.g. as h(x,y)≈R*τ(x,y) where R is an etching rate that may or may not be approximately constant.

The changes in speed are gradual which results in a depth profile that changes correspondingly gradually (i.e. substantially continuously and over a significantly larger distance scale that the grating period d). In practice, the changes in the groove depth h(x,y) are hardly visible (though the effects can be observed from the manner in which light is diffracted). For example, an illustrative case would be to etch gratings whose depth could vary from 300 nm to 150 nm in a distance of 10 mm along the surface.

The depth gradient of the pattern can be expressed as ∇h(x, y) where ∇=(∂ₓ, ∂_{y}) is the gradient function for the xy-plane. As will be apparent, when the aperture size is varied in the manner described above, ∇h(x, y) is non-zero-valued at least some points (x,y) on the surface S′ and varies as a substantially continuous function of xy-position on the surface S′.

A grating pattern exhibiting a continuous slanting angle gradient can be fabricated by effecting relative motion between the aperture 16 and the substrate 5, and simultaneously changing the tilting angle between the ion source 6 and the substrate holder 14, so that different regions of the surface S′ are subject to different tilting angles (i.e. different angles of beam incidence). The aperture motion and tilting angle are varied in a continuous (i.e. smooth) manner to realize continuously changing slanting angles. For example, the tilting may have a substantially constant angular speed to achieve substantially constant slanting angle gradient.

In more general terms, changing pattern slant can be created by effecting relative tilting motion between the surface S′ and the beam 8 (that is, between the shutter-holder system 10/14 and the ion source 6). Varying the relative tilt causes varying angles of beam incidence θ (another example of an exposure condition) i.e. with different points (x,y) on at least a portion of the surface S′ being subject to different “localized” angles of beam incidence θ(x,y), where θ(x,y) represents the angle of beam incidence when the point (x,y) is exposed. When the tilt is greater (resp. lesser), the beam 8 is incident on an exposed point (x,y) at a higher (resp. lower) localized angle of incidence θ(x,y).

The beam angle is varied continuously (i.e. smoothly) as a function of time so that the localized beam angle θ(x,y) to which each point (x,y) is subject varies correspondingly smoothly as a function of position (x,y). This causes a structure with spatially varying slanting angle α(x,y) (which corresponds to “α” as shown in FIGS. 2A-2C) that varies as a function of xy-position in a correspondingly smooth manner, because the slant α(x,y)≈θ(x,y).

The changes in tilt θ are gradual which results in a slant profile that changes correspondingly gradually. As with the depth h(x,y), the scale over which the slant α (x,y) changes is sufficiently large compared to the grating period d that α (x,y) can be effectively considered as a substantially continuous mathematical function of xy-position that is defined at every point (x,y) in the relevant portion of the xy-place. For example, an illustrative case would be to manufacture gratings that have variable slant angle from 20° to 40° in a distance of 10 mm, i.e. 2° per mm.

The slant gradient of the pattern can be expressed as ∇α(x, y). As will be apparent, when the angle of beam incidence is varied in the manner described above, ∇α(x, y) is non-zero-valued at least some points (x,y) on the surface S′ and varies as a substantially continuous function of xy-position on the surface S′.

The shutter plates and/or the substrate holder can be moved, and/or the tilt changed, during the process to create more complex grating profiles, exhibiting continuously and independently varying depth h(x,y) and slant angles α(x,y).

For instance, for a particular fabricated pattern, ∇h(x, y) might be directed in the x direction at some or all points (x,y), which can be achieved by changing the aperture speed as a function of the aperture's current x position (but not y) relative to S′ during fabrication, and ∇α(x, y) might be directed in the y direction which can be achieved by changing the tilting angle as a function of the aperture's y position (but not x) relative to S′ during fabrication. In general, any desired (and possibly spatially varying) directions of ∇d(x, y) and ∇α(x, y) can be independently achieved by controlling the exposure time α(x,y) and tilt θ(x,y) accordingly as a function of the aperture's xy-position relative to S′ during fabrication.

Note that there is no requirement for a point (x,y) to be exposed only in a single window of time e.g. the aperture might pass over any given point (x,y) multiple times during the process—τ(x,y) represents the total time for which the point (x,y) is exposed during the process across one or more exposure windows.

To illustrate some of the principles underlying certain embodiments, a simplified example will now be described with reference to FIG. 4. FIG. 4 is a schematic illustration of the apparatus 1 from the side during a microfabrication process when the ion source 6 is actively generating a substantially collimated particle beam 8. It should be noted that this figure is not to scale and in particular that the distance scale of the surface modulations are greatly enlarged to aid illustration. As mentioned, an illustrative case would be to manufacture gratings that have variable slant angle from 20° to 40° in a distance of 10 mm, i.e. 2° per mm. Over that same distance, the grating depth could vary from 300 nm to 150 nm (though this is just an illustrative example).

In the example of FIG. 4, the substrate holder 14 is moved at a speed v relative to the shutter 10. The substrate 5 is shown with a protective mask layer 20 in the form of a chromium, photoresist or other suitable masking film deposited on the surface S′, which selectively covers the surface S′ in the manner outlined above. In this example, the substrate holder moves in leftwards at a speed v that smoothly increases, thereby decreasing the exposure time as a function of position (x,y) from left to right across the surface S′. As illustrated, this causes the ion beam to create grooves in the surface S′ where not protected by the protective layer 20 whose depth h(x,y) decreases from left to right as a function of position (x,y) due to the more limited exposure.

Simultaneously, the substrate holder is increased from an initial tilting angle at a uniform angular speed ω, thereby resulting in more pronounced beam slant relative to the surface S′ as a function of position (x,y) from left to right. In the simplified example of FIG. 4, the initial tilting angle is around 0 degrees so as to initially create grooves with sides substantially perpendicular to S′ (as can be seen on the left-hand side), but this is only an example and the initial tilting angle can be any desired angle. As illustrated, this causes the ion beam to create the grooves in the surface S′ with slant angles α(x,y) that increases from left to right as a function of position (x,y) due to the changing beam orientation 8 relative to the surface during the microfabrication procedure.

Any of the gratings manufactured using the above-described techniques can have any desired shape (trapezoidal, sinusoidal etc.), with the wall angle γ set by e.g. by choosing an appropriate proportion of reactive and non-reactive gases (“etching parameters”) when etching the substrate. By changing these etching parameters as the aperture/substrate moves, the wall angle γ can be made to vary over the substrate's surface as desired. Typically, this is not expected to vary gradually in the same manner as the linewidth, though that possibility is not excluded.

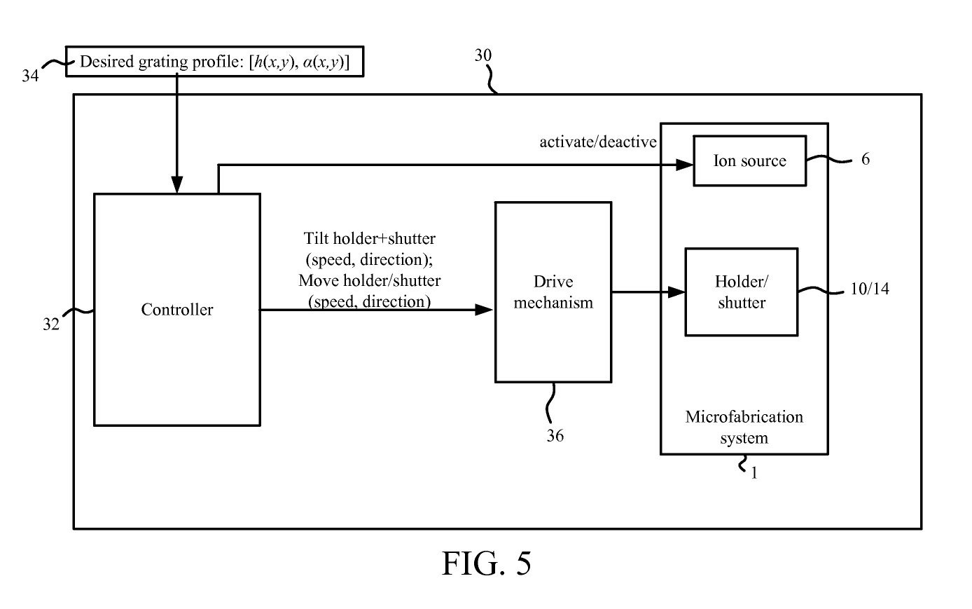

FIG. 5 is block diagram of a microfabrication apparatus 30 incorporating the microfabrication system 1. The system comprises a controller 32 having an input configured to receive desired grating profile information 34 that defines a desired grating profile i.e. that defines the manner in which the grating depth h(x,y) and/or the slant angle α(x,y) are to (continuously) vary as a function of position (x,y) on the surface. The controller has a first output connected to activate/deactivate the ion source 6 at the start/end of a microfabrication procedure in which a grating pattern having the desired grating profile is fabricated on the substrate. The controller is connected to a drive mechanism 36 of the microfabrication tool. The drive mechanism 36 is mechanically coupled to the shutter 10 and/or holder 14 in a manner that enables it to effect controlled movement of the substrate holder 14 and/or the shutter 10. As such, the drive mechanism 38 can be controlled to effect the desired xy-planar and/or rotation motion when the beam is active during microfabrication, detailed above.

The controller 32 converts the desired grating profile information 34 into control signals that are outputted to the drive mechanism during the microfabrication procedure, causing the drive mechanism 36 to move and/or tilt the holder and/or shutter to effect the desired profile in the manner described above. The drive mechanism 36 comprises one or more motors, e.g. in-vacuum stepper motors as mentioned above, that are mechanically coupled to the holder and/or shutter to effect the desired motion.

The controller 32 can be implemented as code executed on a suitable computer system, and the desired profile information 34 can be held in computer storage as data that is accessible to that code when executed.

Embodiments have been described in the context of the manufacturing of surface relief gratings or to the fabrication of grating patterns in general. However, as will be appreciated, the subject matter can be used in the fabrication of many different types of structure on different types of components, both optical and non-optical components (such as integrated circuit components).

The disclosed fabrication approach is also not limited to ion beam etching and can be implemented in any line of sight etching and/or deposition techniques as desired. That is, the techniques can also be used in other line of sight etching and deposition tools (such as electron-gun and thermal evaporators to create thin films, with variable thicknesses). For example, the same shutter mechanism as that described above could be mounted inside an electron-gun evaporator; rather than fabricating continuous depth gradients, in this context thin films with continuous height (i.e. thickness) gradient could be realized. The electrons, when hitting the surface, will create mainly thermal effects with a target substrate. Whilst not suitable for etching, the energetic electrons create changes in some polymers, and this can be used to make masks, as in photolithography. Laser pulses could be used in etching and in that case the target as well as the mask on the target is evaporated by the intense pulse. It would be possible to use such a technique to make e.g. gratings. Laser ablation is an example of this technology that can be used in depositing materials.

Further, whilst in the above an aperture is moved to provide constantly varying exposure times across a substrate surface, other types of relative aperture-substrate motion could be used to achieve a similar effect for instance by varying the aperture size. As an example, the plate 12c of FIG. 3B could be held at a fixed location whilst the plate 12d is continuously moved towards or away from the plate 12c, thereby exposing different points on the substrate's surface S′ to a particle beam for different amounts of time during the microfabrication procedure. Further, whilst in the above different points on a substrate's surface are subject to different levels of beam exposure by varying the exposure time, alternatively or additionally the intensity (that is particle flux) of the beam could be altered to achieve a similar effect. Further, whilst in the above a substrate holder and partitioning system are tilted relative to a beam by driving the substrate holder/partitioning system, alternatively or additionally the ion source could be coupled to the drive system and moved thereby to effect the desired relative tilt. Further, whilst for the above shutter construction, the shape of the etching aperture is always rectangular, but otherwise its size can be changed freely, other shutter constructions are also possible which can provide an aperture any desired aperture shape and size. Further, whilst in the above a shutter mechanism is used to provide an aperture of controllable size e.g. as in FIG. 3B, a partitioning system may be arranged to provide an aperture of fixed size under which a substrate holder is moved and/or which is moved over the holder.

As mentioned according to various aspects of the invention, relative motion is effected between an aperture and a substrate over a portion of the substrate's surface so that different points on the surface portion are exposed at different times. Whilst that motion is ongoing, one or more exposure conditions are varied so that the different points are subject to different exposure conditions, those conditions determining the manner in which the substrate is patterned by the beam at those points, thereby fabricating a pattern on the surface portion having one or more spatially varying characteristics.

In certain embodiments such as those described above, relative motion between the aperture and the substrate is substantially continuous and exposure conditions are varied substantially continuously over time so that the characteristics vary substantially continuously over the surface portion. The exposure conditions may comprise exposure time, which is varied substantially continuously while the motion is ongoing so that different points are subject to different exposure times, the pattern thereby being fabricated to have a spatially varying pattern depth or height that varies substantially continuously over the surface portion. In some of those embodiments, the exposure time is varied by varying, substantially continuously, a relative velocity between a substrate holder which supports the substrate and a partitioning system which provides the aperture, and/or by varying a configuration of the aperture.

Alternatively or additionally, the exposure conditions may comprise angle of beam incidence, which is varied substantially continuously while the motion is ongoing so that different points are subject to different angles of beam incidence, the pattern thereby being fabricated to have spatially varying pattern slanting angles that vary substantially continuously over the surface portion.

However, other embodiments, the relative motion may not be continuous and the exposure conditions (e.g. exposure time/angel of beam incidence) may not be varied substantially continuously. Different points are nonetheless subject to different exposure conditions.

Products that can be obtained by microfabrication processes disclosed herein include an optical component for use in an optical system, or a production master for making optical components, having a diffraction grating pattern etched into a surface portion of the optical component/master by the manufacturing process, the diffraction grating pattern having one or more spatially varying characteristics that vary substantially continuously over the surface portion,

Further, whilst the above considers a substantially software-implemented controller 32, the functionality of the controller can be implemented using software, firmware, hardware (e.g., fixed logic circuitry), or a combination of these implementations. The terms “module,” “functionality,” “component” and “logic” as used herein generally represent, where applicable, software, firmware, hardware, or a combination thereof. In the case of a software implementation, the module, functionality, or logic represents program code that performs specified tasks when executed on a processor (e.g. CPU or CPUs). The program code can be stored in one or more computer readable memory devices. The features of the techniques described below are platform-independent, meaning that the techniques may be implemented on a variety of commercial computing platforms having a variety of processors.

For example, the apparatus may also include an entity (e.g. software) that causes hardware of a computer of the apparatus to perform operations, e.g., processors functional blocks, and so on. For example, the computer may include a computer-readable medium that may be configured to maintain instructions that cause the computer, and more particularly the operating system and associated hardware of the computer to perform operations. Thus, the instructions function to configure the operating system and associated hardware to perform the operations and in this way result in transformation of the operating system and associated hardware to perform functions. The instructions may be provided by the computer-readable medium to the computer through a variety of different configurations.

One such configuration of a computer-readable medium is signal bearing medium and thus is configured to transmit the instructions (e.g. as a carrier wave) to the computing device, such as via a network. The computer-readable medium may also be configured as a computer-readable storage medium and thus is not a signal bearing medium. Examples of a computer-readable storage medium include a random-access memory (RAM), read-only memory (ROM), an optical disc, flash memory, hard disk memory, and other memory devices that may us magnetic, optical, and other techniques to store instructions and other data.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A microfabrication apparatus for fabricating microstructures on a substrate, the apparatus comprising:
a partitioning system arranged to provide an aperture;
a particle source forward of the aperture and configured when active to generate a beam of particles for patterning a substrate, the beam directed towards and encompassing the aperture, wherein the partitioning system inhibits the passage of the beam other than through the aperture;
a substrate holder configured to support the substrate behind the aperture, thereby exposing the substrate to only those parts of the beam which pass through the aperture;
a drive mechanism coupled to the substrate holder and/or the partitioning system; and
a controller configured when the particle source is active to control the drive mechanism to effect relative motion between the aperture and the substrate over a portion of the substrate's surface so that different points on the surface portion are exposed at different times, and whilst that motion is ongoing to vary one or more exposure conditions so that the different points are subject to different exposure conditions, those conditions determining the manner in which the substrate is patterned by the beam at those points, thereby fabricating a pattern on the surface portion having one or more spatially varying characteristics.

2. A microfabrication apparatus according to claim 1, wherein the relative motion is substantially continuous and the exposure conditions are varied substantially continuously over time so that the characteristics vary substantially continuously over the surface portion.

3. A microfabrication apparatus according to claim 1, wherein the exposure conditions comprise exposure time, which is varied while the motion is ongoing so that different points are subject to different exposure times, the pattern thereby being fabricated to have a spatially varying pattern depth or height that over the surface portion.

4. A microfabrication apparatus according to claim 3 wherein the exposure time is varied by controlling the drive mechanism to vary a relative velocity between the substrate holder and the partitioning system and/or a configuration of the aperture.

5. A microfabrication apparatus according to claim 1 wherein the exposure conditions comprise angle of beam incidence, which is varied while the motion is ongoing so that different points are subject to different angles of beam incidence, the pattern thereby being fabricated to have spatially varying pattern slanting angles that vary over the surface portion.

6. A microfabrication apparatus according to claim 5 wherein the angle of beam incidence is varied by controlling the drive mechanism to tilt the substrate holder with the partitioning system relative to the particle source, the substrate holder and the partitioning system thereby remaining aligned with one another when tilted.

7. A microfabrication apparatus according to claim 1, wherein the exposure conditions comprise exposure time and angle of beam incidence, which are both varied while the motion is ongoing so that different points are subject to both different exposure times and different angles of beam incidence, the pattern thereby being fabricated to have both spatially varying pattern depth or height and spatially varying slanting angles, both of which vary over the surface portion.

8. A microfabrication method according to claim 7 wherein the exposure time and angle of beam incidence are varied independently of one another.

9. A microfabrication apparatus according to claim 1, wherein the drive mechanism is coupled to the substrate holder and is controllable to move the substrate holder while the aperture remains at a substantially fixed location relative to the particle source.

10. A microfabrication apparatus according to claim 1, wherein the partitioning system comprises a shutter mechanism coupled to the drive mechanism, the drive mechanism controllable to adjust a configuration of the aperture by driving the shutter mechanism.

11. A microfabrication apparatus according to claim 10 wherein the shutter mechanism is formed of multiple shutter plates that are independently controllable.

12. A microfabrication apparatus according to claim 1 wherein the substrate is supported at a location behind the aperture such that the surface portion is separated from the partitioning system by no more than about 5 mm.

13. A microfabrication apparatus according to claim 1 wherein the particle source is an ion source configured to generate a beam of ions.

14. A microfabrication process for fabricating microstructures on a substrate, in which the substrate is supported behind an aperture provided by a partitioning system with a particle source forward of the aperture configured when active to generate a beam of particles for patterning the substrate, wherein the beam is directed towards and encompasses the aperture and the partitioning system inhibits the passage of the beam other than through the aperture so that the substrate is exposed to only those parts of the beam which pass through the aperture, the process comprising:
when the particle source is active, effecting relative motion between the aperture and the substrate over a portion of the substrate's surface so that different points on the surface portion are exposed at different times; and
whilst that motion is ongoing, varying one or more exposure conditions so that the different points are subject to different exposure conditions, those conditions determining the manner in which the substrate is patterned by the beam at those points, thereby fabricating a pattern on the surface portion having one or more spatially varying characteristics.

15. A microfabrication process according to claim 14, wherein the beam is for etching the substrate and the pattern is fabricated by the beam etching the pattern into the surface.

16. A microfabrication process according to claim 15 wherein the etched pattern is a diffraction grating pattern.

17. A microfabrication process according to claim 13 wherein the beam is for depositing a film on the substrate, the pattern being a film deposited on the substrate by the beam when active, the film having the one or more spatially varying characteristics that vary over the surface portion.

18. A microfabrication process according to claim 13 wherein the patterned substrate is for use as an optical component in an optical system, or the patterned substrate is for use as a production master for manufacturing optical components and the process further comprises using the production master to manufacture optical components.

19. A product obtained by the microfabrication process of claim 13.

20. A microfabrication apparatus for fabricating microstructures on a substrate, the apparatus comprising:
a partitioning system arranged to provide an aperture;
a particle source forward of the aperture and configured when active to generate a beam of particles for patterning a substrate, the beam directed towards and encompassing the aperture, wherein the partitioning system inhibits the passage of the beam other than through the aperture;
a substrate holder configured to support the substrate behind the aperture, thereby exposing the substrate to only those parts of the beam which pass through the aperture;
a drive mechanism coupled to the substrate holder and/or the partitioning system; and
a controller configured when the particle source is active to control the drive mechanism to effect relative motion between the aperture and the substrate over a portion of the substrate's surface so that different points on the surface portion are exposed at different times, and whilst that motion is ongoing to vary one or more exposure conditions so that the different points are subject to different exposure conditions, those conditions determining the manner in which the substrate is patterned by the beam at those points, thereby fabricating a pattern on the surface portion having one or more spatially varying characteristics;
wherein the relative motion is substantially continuous and the exposure conditions are varied substantially continuously over time so that the characteristics vary substantially continuously over the surface portion; and
wherein the exposure conditions comprise exposure time and angle of beam incidence, which are both varied substantially continuously while the motion is ongoing so that different points are subject to both different exposure times and different angles of beam incidence, the pattern thereby being fabricated to have both spatially varying pattern depth or height and spatially varying slanting angles, both of which vary substantially continuously over the surface portion.
